(19) United States
(12) Patent Application Publication
(10) Pub. No.: US 2024/0061059 A1
(43) Pub. Date: Feb. 22, 2024

(54) SYSTEM AND METHOD FOR OPERATION AND CONTROL OF ELECTROMAGNETS

(71) Applicant: SYNAPTIVE MEDICAL INC., Toronto (CA)

(72) Inventors: Chad Tyler HARRIS, Toronto (CA); Geron Andrè BINDSEIL, London (CA); Philip J. BEATTY, Thornhill (CA); Andrew Thomas CURTIS, Ajax (CA)

(73) Assignee: SYNAPTIVE MEDICAL INC., Toronto (CA)

(21) Appl. No.: 18/169,978

(22) Filed: Feb. 16, 2023

Related U.S. Application Data
(60) Provisional application No. 63/268,150, filed on Feb. 17, 2022.

(51) Int. Cl. G01R 33/54; G01R 33/381; G01R 33/56; G01R 33/385; G01R 33/48

(52) U.S. Cl. CPC G01R 33/543; G01R 33/381; G01R 33/5608; G01R 33/385; G01R 33/4826

(57) ABSTRACT

A system and method for enhancing magnetic resonance imaging is described. The method includes a declarative style of pulse sequence design that incorporates explicit objectives. Each objective includes the function and context of the waveform; environmental and contextual data; time segment durations; spatial magnetic field profiles of the encoding electromagnets; and performance metrics.

### CROSS-REFERENCE TO RELATED APPLICATIONS

This document is a nonprovisional patent application claiming the benefit of, and priority to, U.S. Provisional Patent Application No. 63/268,150, entitled “SYSTEM AND METHOD FOR OPERATION AND CONTROL OF ELECTROMAGNETS,” and filed on Feb. 17, 2022, hereby incorporated by reference in its entirety.

### FIELD

The present disclosure is related to systems and methods for magnetic resonance imaging. More particularly, the disclosure relates to systems and methods for pulse sequence generation and control of an electromagnet system.

### BACKGROUND

Magnetic resonance imaging (MRI) is generally performed with very strong static magnetic fields. The static magnetic field, referred to as the “main field” or “BO field”, is responsible for polarizing nuclei and is required for imaging during nuclear magnetic resonance.

Traditional MRI utilizes three orthogonal magnetic fields, also known as gradient fields, in order to produce an image. These three fields are created by three distinct coils, known as gradient coils. Gradient coils are designed to produce linearly varying magnetic fields over the field of view. The field that a gradient coil produces will deviate from perfectly linear by a certain degree. This is called gradient non-linearity. Gradient non-linearity can result in non-uniform, potato-chip-like slice profiles; image distortion; and non-uniform encoding fields (e.g. diffusion weighted encoding).

In addition to gradient non-linearity, the fast switching on and off of the gradient fields required for typical imaging can lead to peripheral nerve stimulation (PNS). PNS can be painful and dangerous to the patient. To avoid PNS, gradient slew rates are typically limited, which elongates scan time.

The electromagnets within an MRI system are also responsible for active magnetic field shimming. Active magnetic field shimming is traditionally done by spherical harmonic analysis, with a set of dedicated electromagnets, each capable of producing a single distinct spherical harmonic spatial variation in the field in the imaging region. In this way, the electromagnets of a traditional MRI system form a spherical harmonic basis set. This is a convenient basis set, as it is orthogonal, which allows minimal inductive coupling and high efficiency.

There has been work on a different approach to generating the gradient and shim fields using a set of electromagnets that do not form an orthogonal basis set. These sets of non-orthogonal electromagnets have been known as “multi-coils” or “matrix-coils” and typically consist of an array of a large number of simple small coil elements, such as loops. For example, these multi-coil sets have been used for human brain imaging.

In existing pulse sequence design methodology, designers specify pulse sequences as a set of waveforms along a set of logical axes. Each waveform specifies the temporal variation of a signal along a particular axis. For example, a trapezoidal waveform might be specified on the logical X gradient axis.

It is also common that the waveforms along the set of logical axes are transformed to waveforms along a set of physical axes. This is usually accomplished by rotation, scaling, and shifting transformations. There is typically a single mapping of logical to physical coordinates based on the relation between the target imaging region and the location/orientation of the physical hardware elements.

Typically, no information as to the purpose of the waveforms is transmitted by the pulse sequence to the system that is creating the physical waveforms. Furthermore, the system that processes the pulse sequence to create physical waveforms is simply carrying out a mapping between logical and physical spaces (coordinates) and does not use any additional objectives in forming the physical control waveforms.

In addition, designing pulse sequences to be generated using multi-coil hardware is cumbersome. Multi-coil control typically consists of a separate, independent, waveform controller that is distinct from the main system gradient or shim control. Generally, a traditional 3-axis (i.e., x, y and z) pulse sequence (i.e., a pulse sequence designed to be inputted to a set of orthogonal gradient coils) must be converted to a multi-coil pulse sequence (i.e., a pulse sequence designed to be inputted to a set of multi-coils) ahead of time, prior to imaging. This prevents the possibility of real-time adjustment of the imaging field of view or orientation.

Furthermore, current multi-coil approaches for imaging have a limited achievable gradient strength. This is due both to amplifier limitations as well as the inherent inefficiency of a non-orthogonal basis set to produce field patterns. This limitation is most noticeable for imaging sequences that require high-gradient amplitudes such as diffusion imaging.

### SUMMARY

A system and method for enhancing magnetic resonance imaging are described. The method includes a declarative style of pulse sequence design that incorporates explicit objectives. Each objective includes the function and context of the waveform; environmental and contextual data; time segment durations; spatial magnetic field profiles of the encoding electromagnets; and performance metrics.

According to this disclosure, pulse sequences are written in a declarative style, where the objective is included as part of the pulse sequence. In the present disclosure, an “objective” includes the following:
1. The function and context of the waveform (e.g., encoding; contrast; preparation)
2. Environmental and contextual data (e.g., imaging region; constraint region—heart, peripheral nerves; background magnetic field; etc.)
3. Time segment durations
4. Spatial magnetic field profile of the encoding electromagnets (e.g., gradient coils; multi-coil array; etc.)
5. Performance metrics (e.g., total phase accumulation; mean-squared error (MSE) of field linearity; maximum dB/dt; MSE of field homogeneity; minimum concomitant magnetic fields; minimum of the maximum slice warping; uniform contrast encoding; maximum contrast encoding; etc.)

The end result is a pulse sequence that describes a set of instructions for the MR system to play out that is in stark contrast to a simple set of waveforms in logical coordinates, which is imperative.

Application areas where we see this invention making a difference are:
1. Slice thickness uniformity
2. Slice shape fidelity
3. Reducing peripheral nerve stimulation over a sub-volume of the object
4. Diffusion encoding uniformity

The foregoing and other aspects and advantages of the present disclosure will appear in the following description. In the description, reference is made to the accompanying drawings that form a part hereof, and in which there is shown by way of illustration a preferred embodiment. Such embodiment does not necessarily represent the full scope of the disclosure, however, and reference is made therefore to the claims and herein for interpreting the scope of the disclosure.

### BRIEF DESCRIPTION OF THE DRAWINGS

Reference will now be made, by way of example, to the accompanying drawings which show example embodiments of the present application, and in which:

FIG. 1 is a block diagram of an example magnetic resonance imaging (“MRI”) system, which incorporates an electromagnetic system.

FIG. 2 are graphs illustrating gradient fields profiles with and without the use of enhancement from a supplementary electromagnet system during magnetic resonance imaging.

FIG. 3 is a graph illustrating current flow through a main gradient coil and coils in a multi-coil supplementary electromagnet system at different positions in the imaging region during magnetic resonance imaging.

### DETAILED DESCRIPTION

A method and system for enhancing magnetic resonance imaging with a multi-coil matrix with multiple multi-coil elements are described. The method includes inputting target x, y, and z pulse sequences having linear gradients into a convolutional network, the convolutional network being configured to decompose the target x, y, and z pulse sequences into respective multi-coil waveforms, wherein each of the respective multi-coil waveforms is a respective real function. The method further includes exciting the multi-coil matrix with the respective multi-coil waveforms to generate multi-coil gradient fields in an imaging region of the MRI system.

Described herein are systems and methods for operating and controlling electromagnets in an MRI system. In particular, the present disclosure describes a declarative style of pulse sequence design, where the objective is included as part of the pulse sequence. The end result is a pulse sequence that describes a set of instructions for the MR system to play out that is in stark contrast to a simple set of waveforms in logical coordinates, which, during magnetic resonance imaging, help increase system performance, such as by reducing gradient non-linearity over the excitation volume.

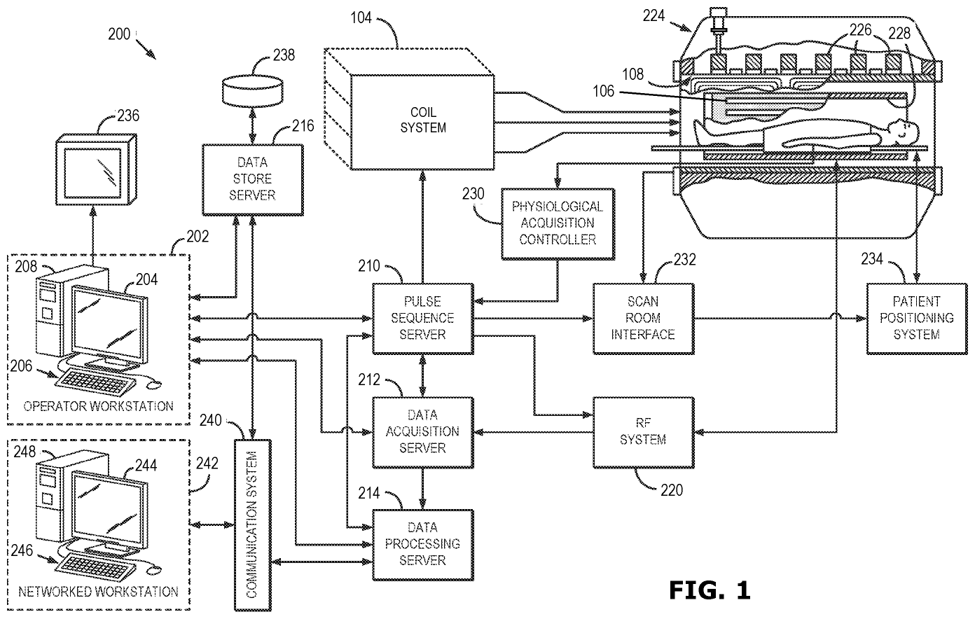

Referring to FIG. 1, there is illustrated a schematic of an electromagnet system 104 for use in a magnetic resonance imaging (MRI) system 200 during magnetic resonance imaging. The electromagnet system 104 comprises an orthogonal gradient set and may or may not include a high-order active shim set and/or a multi-coil array. The additional electromagnets (e.g. multi-coil array), may be placed within the same structure as the orthogonal gradient set or closer to the patient.

In the case where the electromagnet system 104 includes a multi-coil array, each element may be a coil with a small diameter. If this array is placed in close proximity to the patient during imaging, each multi-coil element has a high sensitivity but limited anatomical coverage. The multi-coil array may have a shape/arrangement that is suitable for the particular geometry of the MRI system, and for the size and shape of the imaging region. The multi-coil elements may be constructed of wound wire loops, where each element may be identical, and each identical element may be arrayed in different locations around the imaging region.

In various examples, the dimensions of the multi-coil elements, including their shape and layout in the array, may be designed, selected and/or arranged differently in order to achieve particular objectives, as will be discussed further below.

The electromagnet control system is configured to receive a pulse sequence that includes an objective. In this disclosure, an “objective” includes the following:
1. The function and context of the waveform (e.g., encoding; contrast; preparation)
2. Environmental and contextual data (e.g., imaging region; constraint region—heart, peripheral nerves; background magnetic field; etc.)
3. Time segment durations
4. Spatial magnetic field profile of the encoding electromagnets (e.g., gradient coils; multi-coil array; etc.)
5. Performance metrics (e.g., total phase accumulation; mean-squared error (MSE) of field linearity; maximum dB/dt; MSE of field homogeneity; minimum concomitant magnetic fields; minimum of the maximum slice warping; uniform contrast encoding; maximum contrast encoding; etc.)

In an example embodiment, the pulse sequence would declare a certain desired slice thickness and/or slice profile. The electromagnet control system that consumes the pulse sequence and controls the hardware would then determine the appropriate waveforms to play to achieve this.

For a hypothetical system with perfectly linear gradient fields, a specific slice thickness (and additional parameters like time-bandwidth product, etc.) maps to a specific set of logical waveforms, which can then be mapped to a specific set of physical waveforms. Traditional pulse sequence design relies on this simplifying assumption. However, for a real system with non-linear gradient fields, such an approach leads to a loss of fidelity and cannot achieve an optimal result. This loss of fidelity is worse for gradient systems with greater non-linearity in the gradient field, such as for the case of anatomy-specific asymmetric gradient coils.

In this example embodiment, the electromagnet control system that processes the pulse sequence to create physical waveforms uses the declarative information within the pulse sequence to, for example, create different waveforms depending on the imaging region location in order to best match the desired slice profile/thickness at that position.

Previously, if someone wanted to account for the non-linearity of the gradients at a certain imaging region, they would need to design a custom pulse sequence that would only be valid for a specific scanner and imaging region—it would not be portable. With our approach, a single pulse sequence can be applicable to scanners with different hardware configurations. In addition, a user can, for example, change the positioning of the imaging region without (a) requiring a redesign of the pulse sequence or (b) suffering a loss in fidelity due to a mismatch between the imaging region during the pulse sequence design and application phases.

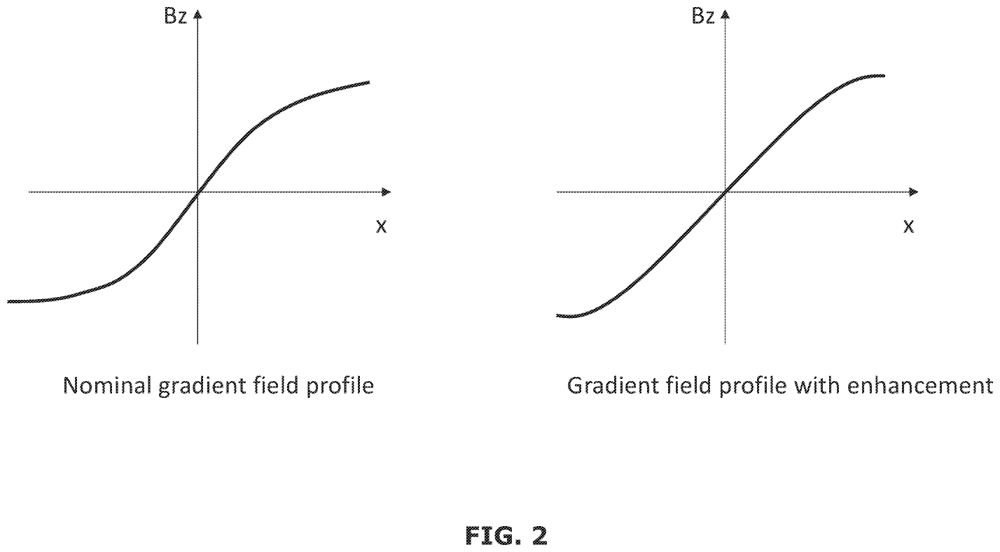

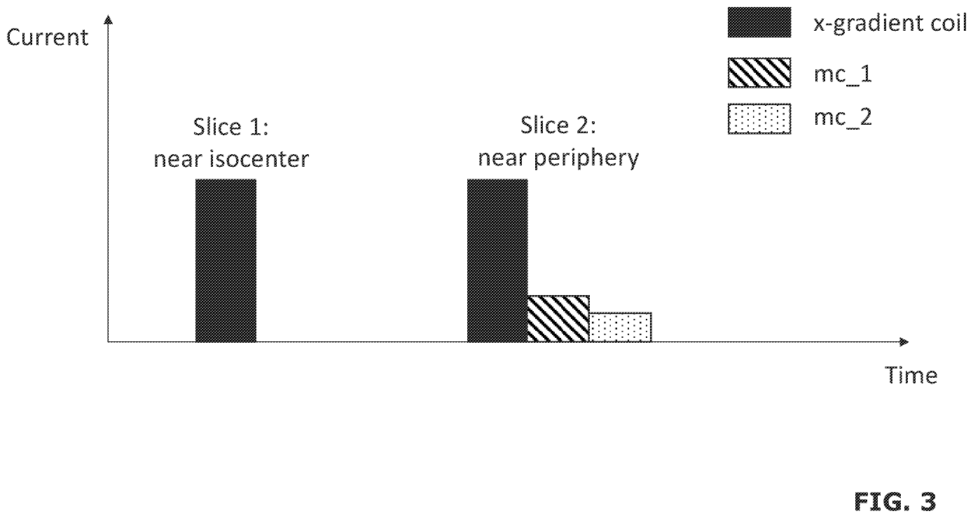

Further performance can be gained if the MR system includes control of additional (non-gradient) electromagnets (e.g. a multi-coil array). In this scenario, the additional electromagnets work alongside the system's gradient coils to help optimize the objective. FIGS. 2-3 illustrate an example of performance enhancement that may be provided using the additional (non-gradient) electromagnets. FIG. 2 shows a nominal gradient field profile (left) when traditional gradient coils are used during imaging without additional electromagnets. With the use of auxiliary electromagnets, and an objective that gives preference to increasing gradient linearity, the gradient field profile is shown to be more linear (right).

The performance enhancement provided by the auxiliary electromagnets can vary throughout the pulse sequence and can be based on environmental contextual data (e.g., excitation volume location). FIG. 3 is a graph illustrating current flow through the orthogonal gradient set and multi-coil elements in electromagnet system 104 at different positions in the imaging region during MRI. Near isocenter, where the gradient non-linearity is minimal, no enhancement needs to be used. Conversely, near the periphery of the field of view, where the gradient non-linearity is largest, enhancement (i.e., mc_1, mc_2) may be used.

In an alternate embodiment, the control methodology could be applied to an MRI system that does not include a typical three-axis gradient coil set, and instead includes an array of electromagnets that are controlled independently and may have identical or disparate electromagnetic designs among the set.

In another embodiment, the control methodology could apply to an MRI system with additional RF transmit channels or spatially localized transmitter elements to improve or provide targeted RF excitation.

According to the disclosure, a method of producing a series of control waveforms for a magnet resonance imaging (MRI) apparatus is disclosed. The method comprises the steps of receiving system hardware configuration input from the MRI, receiving environmental data input from the MRI and calculating/generation one or more optimization objectives. The context and/or intended use case of each waveform is known and each waveform is uniquely designed and created.

According to the disclosure, the optimization objectives of the method is selected from a list consisting of delivering specified gradient moments (area) in specified time intervals, whether minimum time, or desired longer durations, creating a gradient field suitable for slice or volume selective RF excitation, creating a spoiler, flow compensation, phase encoding, or diffusion gradient with specified gradient moments, creating a readout gradient suitable for uniform k-space readouts, non-uniform (ramp-sampling), or non-Cartesian readouts, limiting electric field induced nerve stimulation around localized regions, reducing warping of an excited volume in the imaging region, increasing gradient linearity over a field of view and balancing signal-to-noise ratio (SNR) and resolution in localized regions.

According to the disclosure, the system hardware configuration and environmental data is selected form a list consisting of, knowledge of the spatial magnetic and/or electric field profiles of the available electromagnets of the system, knowledge of the main background magnetic field of the system, knowledge of the spatial magnetic and/or electric field profiles of the available transmit radiofrequency coils of the system, knowledge of the receiver coil sensitivity profiles of the system, location of the desired imaging region and location of additional constraint targeted region (e.g. where a particular region of interest should have minimal electric field exposure).

According to the disclosure, a the available electromagnets of the system hardware configuration consists of a linear electromagnet set (gradient set) and a high spatial order electromagnet set. The the high spatial order electromagnet set produces magnetic field profiles that create an orthogonal basis set (e.g. a spherical harmonic basis). The high spatial order electromagnet set produces magnetic field profiles that do not create an orthogonal basis set (multi-coil).

According to the disclosure, a the coil elements of the high spatial order electromagnet set has different shapes relative to one another. The coil element shapes are designed to reduce inductive coupling with other coil elements. The coil elements are connected to an amplifier, the amplifier configured to apply an opposite voltage to the coil element to prevent inductive coupling with the gradient coils.

According to the disclosure, the step of selecting from a set of waveforms in a look up table according to the inputs (system and environmental data, stated objectives, context/intended use).

According to the disclosure, the step of solving a mathematical optimization problem wherein the mathematical optimization problem is selected from a list consisting of least squares, minimizing the maximum, linear programming, or subject to specific constraints, and including maximum values.

According to the disclosure, the optimization objectives of change throughout a scanning session. The selected optimization objectives are solved in a single optimization problem, such as by a multi-objective optimization, ranked or weighted in level of importance, or combined via Lagrange multipliers. The output is used to control the MRI system.

According to the disclosure, the output is used to control the MRI system and both the output and input is communicated to the reconstruction engine. The input consists of the system hardware configuration and environmental data, plurality of optimization objectives, and knowledge/intended use of the waveforms. The information communicated to the reconstruction engine is a subset/modified version of the inputs provided to the waveform optimization method.

While some embodiments or aspects of the present disclosure may be implemented in fully functioning computers and computer systems, other embodiments or aspects may be capable of being distributed as a computing product in a variety of forms and may be capable of being applied regardless of the particular type of machine or computer readable media used to actually effect the distribution.

At least some aspects disclosed may be embodied, at least in part, in software. That is, some disclosed techniques and methods may be carried out in a computer system or other data processing system in response to its processor, such as a microprocessor, executing sequences of instructions contained in a memory, such as read-only memory (ROM), volatile random access memory (RAM), non-volatile memory, cache or a remote storage device.

A computer readable storage medium may be used to store software and data which when executed by a data processing system causes the system to perform various methods or techniques of the present disclosure. The executable software and data may be stored in various places including for example ROM, volatile RAM, non-volatile memory and/or cache. Portions of this software and/or data may be stored in any one of these storage devices.

Examples of computer-readable storage media may include, but are not limited to, recordable and non-recordable type media such as volatile and non-volatile memory devices, ROM, RAM, flash memory devices, floppy and other removable disks, magnetic disk storage media, optical storage media (e.g., compact discs (CDs), digital versatile disks (DVDs), etc.), among others. The instructions can be embodied in digital and analog communication links for electrical, optical, acoustical or other forms of propagated signals, such as carrier waves, infrared signals, digital signals, and the like. The storage medium may be the internet cloud, or a computer readable storage medium such as a disc.

Furthermore, at least some of the methods described herein may be capable of being distributed in a computer program product comprising a computer readable medium that bears computer usable instructions for execution by one or more processors, to perform aspects of the methods described. The medium may be provided in various forms such as, but not limited to, one or more diskettes, compact disks, tapes, chips, USB keys, external hard drives, wire-line transmissions, satellite transmissions, internet transmissions or downloads, magnetic and electronic storage media, digital and analog signals, and the like. The computer useable instructions may also be in various forms, including compiled and non-compiled code.

At least some of the elements of the systems described herein may be implemented by software, or a combination of software and hardware. Elements of the system that are implemented via software may be written in a high-level procedural language such as object oriented programming or a scripting language. Accordingly, the program code may be written in C, C++, J++, or any other suitable programming language and may comprise modules or classes, as is known to those skilled in object oriented programming. At least some of the elements of the system that are implemented via software may be written in assembly language, machine language or firmware as needed. In either case, the program code can be stored on storage media or on a computer readable medium that is readable by a general or special purpose programmable computing device having a processor, an operating system and the associated hardware and software that is necessary to implement the functionality of at least one of the embodiments described herein. The program code, when read by the computing device, configures the computing device to operate in a new, specific and predefined manner in order to perform at least one of the methods described herein.

While the teachings described herein are in conjunction with various embodiments for illustrative purposes, it is not intended that the teachings be limited to such embodiments. On the contrary, the teachings described and illustrated herein encompass various alternatives, modifications, and equivalents, without departing from the described embodiments, the general scope of which is defined in the appended claims. Except to the extent necessary or inherent in the processes themselves, no particular order to steps or stages of methods or processes described in this disclosure is intended or implied. In many cases the order of process steps may be varied without changing the purpose, effect, or import of the methods described.

1. A method of producing a series of control waveforms for a magnet resonance imaging (MRI) apparatus, the method comprising the steps of:
receiving system hardware configuration input from the MRI;
receiving environmental data input from the MRI; and
calculating/generation one or more optimization objectives;
wherein context and/or intended use case of each waveform is known;
wherein each waveform is uniquely designed and created:

2. The method of claim 1 wherein the optimization objectives is selected from a list consisting of:
delivering specified gradient moments in specified time intervals, minimum time, or desired longer durations;
creating a gradient field suitable for slice or volume selective RF excitation;
creating a spoiler, flow compensation, phase encoding, or diffusion gradient with specified gradient moments;
creating a readout gradient suitable for uniform k-space readouts, non-uniform ramp-sampling, or non-Cartesian readouts;
limiting electric field induced nerve stimulation around localized regions;
reducing warping of an excited volume in the imaging region;
increasing gradient linearity over a field of view; and
balancing signal-to-noise ratio (SNR) and resolution in localized regions.

3. The method of claim 1 wherein the system hardware configuration and environmental data is selected form a list consisting of:
knowledge of the spatial magnetic or electric field profiles of the available electromagnets of the system;
knowledge of the main background magnetic field of the system;
knowledge of the spatial magnetic or electric field profiles of the available transmit radiofrequency coils of the system;
knowledge of the receiver coil sensitivity profiles of the system;
location of the desired imaging region; and
location of additional constraint targeted region.

4. The method of claim 3 wherein the available electromagnets of the system hardware configuration 3 consists of a linear electromagnet set and a high spatial order electromagnet set.

5. The method of claim 4 wherein the high spatial order electromagnet set produces magnetic field profiles that create an orthogonal basis set.

6. The method of claim 4 wherein the high spatial order electromagnet set produces magnetic field profiles that do not create an orthogonal multi-coil basis set.

7. The method of claim 6 wherein the coil elements of the high spatial order electromagnet set has different shapes relative to one another.

8. The method of claim 7 wherein the coil element shapes are designed to reduce inductive coupling with other coil elements.

9. The method of claim 6 wherein the coil elements are connected to an amplifier, the amplifier configured to apply an opposite voltage to the coil element to prevent inductive coupling with the gradient coils.

10. The method of claim 1 further comprising the step of selecting from a set of waveforms in a look up table according to the inputs.

11. The method of claim 1 further comprising the step of solving a mathematical optimization problem.

12. The method of claim 11 wherein the mathematical optimization problem is selected from a list consisting of least squares, minimizing the maximum, linear programming, or subject to specific constraints, and including maximum values.

13. The method of claim 2 wherein the optimization objectives of change throughout a scanning session.

14. The method of claim 2 wherein the selected optimization objectives are solved in a single optimization problem, such as by a multi-objective optimization, ranked or weighted in level of importance, or combined via Lagrange multipliers.

15. The method of claim 1 wherein the output is used to control the MRI system.

16. The method of claim 1 wherein the output is used to control the MRI system and both the output and input is communicated to the reconstruction engine.

17. The method of claim 1 wherein the input consists of the system hardware configuration and environmental data, plurality of optimization objectives, and knowledge use of the waveforms.

18. The method of claim 16 wherein the information communicated to the reconstruction engine is a subset or modified version of the inputs provided to the waveform optimization method.
